(19) United States
(12) Patent Application Publication
(10) Pub. No.: US 2021/0184468 A1
(43) Pub. Date: Jun. 17, 2021

(54) BYPASS MODULE FOR ENHANCED PV ARRAY DC-AC RATIO CAPABILITY

(71) Applicant: GE Energy Power Conversion Technology Limited, Warwickshire (GB)

(72) Inventors: David Rudniski, Mississauga (CA); Robert Gregory Wagoner, Salem, VA (US)

(73) Assignee: GE Energy Power Conversion Technology Limited, Warwickshire (GB)

(21) Appl. No.: 16/714,514

(22) Filed: Dec. 13, 2019

(51) Int. Cl. H02J 3/38; H02S 50/00; H02S 40/32

(52) U.S. Cl. CPC H02J 3/381; H02J 2300/26; H02S 40/32; H02S 50/00

(57) ABSTRACT

Provided is a control system for a PV array system including a plurality of PV panels. The control system includes a bypass module having a first switch device and a second switch device disposed at at least one PV panel connected with others of the plurality of PV panels along a string, and configured to perform a switching operation when PV voltage at the at least one PV panel is outside of an acceptable voltage range of the PV array system, and the bypass module short-circuits the PV panel when excess voltage at the PV panel is detected. The control system also including a control module configured to monitor and control operation of the bypass module.

### I. TECHNICAL FIELD

The present invention relates generally to photovoltaic (PV) array systems. In particular, the present invention relates to a bypass module for enhancing the PV array DC-AC ratio capability within a PV array system.

### II. BACKGROUND

A PV array system is typically connected to an input of an electric power system to convert and transmit power to the electric power system. It includes PV arrays, a combiner box connected thereto and a PV inverter to convert the power from DC to AC power for the electric power system (e.g., a utility grid). In order to maximize power of the PV array system, it is common for the system to be designed with higher power-rated PV arrays than the power rating of the PV inverter. During operation, the system covers different environmental conditions, some resulting in a higher output power capability of the PV arrays which includes a higher voltage and current capability than the PV inverter is able to operate. Cold weather causes an increase of the PV open-circuit voltage, and high irradiance (e.g., >full sun) causes an increase of the PV short-circuit current. These factors combined can result in a PV array with a much higher power capability than that of the PV inverter.

During operation it is desirable to operate the PV inverter at a power level that maximizes the AC power supplied to utility grid. Therefore, it is desirable to have the highest possible DC-to-AC ratio which increases the chance of a PV inverter tripping or being damaged. Thus, enhancement of the PV array DC-AC ratio in a PV array system without causing problems within the PV inverter is desired.

### III. SUMMARY OF THE EMBODIMENTS

According to one embodiment, a bypass module is employed in a string at one or more of the PV panels to bypass the respective PV panel when the PV voltage is above an acceptable voltage range to avoid tripping or damaging a PV inverter of a PV array system.

Embodiments of the present invention provides a control system for a PV array system including a plurality of PV panels. The control system includes a bypass module having a first switch device and a second switch device disposed at at least one PV panel connected with others of the plurality of PV panels along a string, and configured to perform a switching operation when PV voltage of at least one PV panel is outside of an acceptable voltage range of the PV array system, and e bypass module short-circuits the PV panel when excess voltage at the PV panel is detected. The control system also including a control module configured to monitor and control operation of the bypass module.

Other embodiments of the present invention include a bypass method for performing a bypass operation at at least one of the PV panels of the PV array system.

The foregoing has broadly outlined some of the aspects and features of various embodiments, which should be construed to be merely illustrative of various potential applications of the disclosure. Other beneficial results can be obtained by applying the disclosed information in a different manner or by combining various aspects of the disclosed embodiments. Accordingly, other aspects and a more comprehensive understanding may be obtained by referring to the detailed description of the exemplary embodiments taken in conjunction with the accompanying drawings, in addition to the scope defined by the claims.

### IV. DESCRIPTION OF THE DRAWINGS

The drawings are only for purposes of illustrating preferred embodiments and are not to be construed as limiting the disclosure. Given the following enabling description of the drawings, the novel aspects of the present disclosure should become evident to a person of ordinary skill in the art. This detailed description uses numerical and letter designations to refer to features in the drawings. Like or similar designations in the drawings and description have been used to refer to like or similar parts of embodiments of the invention.

FIG. 1 is a schematic illustrating a PV array system that can be implemented within embodiments of the present invention.

FIG. 2 is a circuit schematic of PV panel string that includes a bypass module at one PV panel of a plurality of PV panels of the PV array system of FIG. 1, to bypass the PV panel during high voltage conditions, that can be implemented within the embodiments of the present invention.

FIG. 3 is a circuit schematic of a control module of the bypass module of FIG. 2, that can be implemented within embodiments of the present invention.

FIG. 4 is a flow chart illustrating a bypass process of the bypass module of FIGS. 2 and 3, that can be implemented within the embodiments.

FIG. 5 is a graph of a PV bypass waveforms formed upon implementation of the bypass module of FIGS. 2 and 3, that can be implemented within embodiments of the present invention.

### V. DETAILED DESCRIPTION OF THE EMBODIMENTS

As required, detailed embodiments are disclosed herein. It must be understood that the disclosed embodiments are merely exemplary of various and alternative forms. As used herein, the word “exemplary” is used expansively to refer to embodiments that serve as illustrations, specimens, models, or patterns. The Figures are not necessarily to scale and some features may be exaggerated or minimized to show details of particular components.

In other instances, well-known components, apparatuses, materials, or methods that are known to those having ordinary skill in the art have not been described in detail in order to avoid obscuring the present disclosure. Therefore, specific structural and functional details disclosed herein are not to be interpreted as limiting, but merely as a basis for the claims and as a representative basis for teaching one skilled in the art.

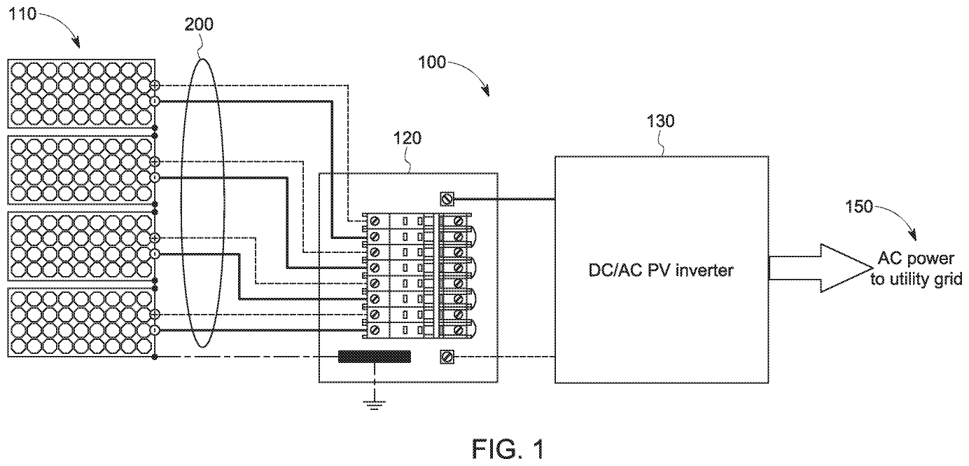

As noted above, the embodiments provide a bypass module that can be implemented in connection with one or more PV panels within a string to be connected with a combiner box (as depicted in FIG. 1). As shown in FIG. 1, a PV array system 100 includes a plurality of PV panels 110 each formed of multiple cells connected into a combiner box 120 which is connected to a DC/AC PV inverter 130 and converts DC power to AC power to be supplied to a utility grid 150. The PV panels 110 are arranged in series to stack up to a desired total voltage appropriate for the PV inverter 130. The combiner box 120 brings together the multiple strings 200 from the PV cells, each string 200 at a low current and combines them together into a high current output for the PV inverter 130.

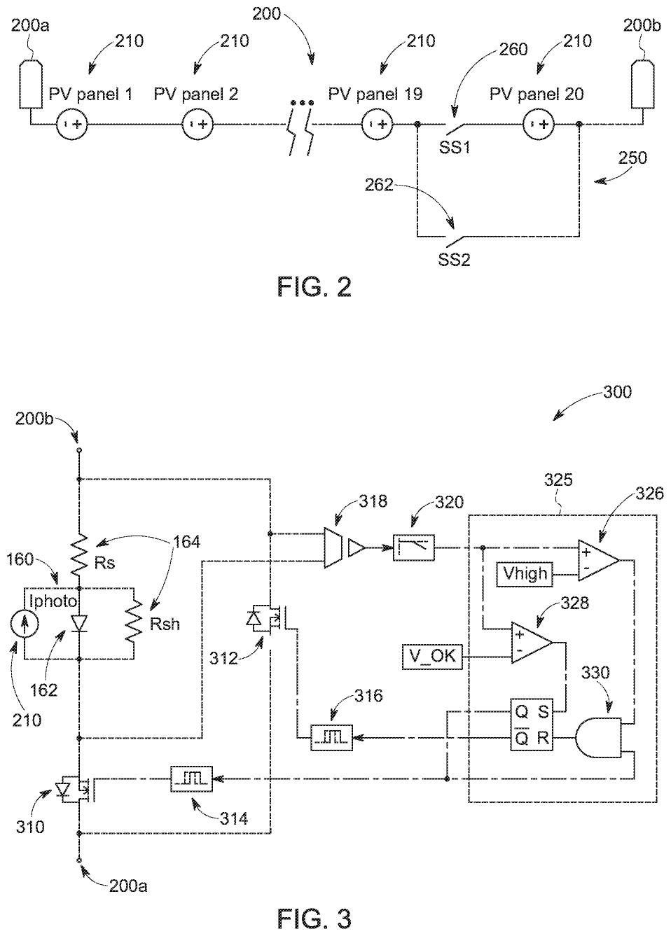

Details regarding the bypass module 250 will be discussed below with reference to FIG. 2. As shown in FIG. 2, a string 200 having a negative terminal 200a and a positive terminal 200b, connects multiple PV panels 110 (e.g., PV panel 1, PV panel 2 . . . PV panel 19 and PV panel 20). Each PV panel 110 includes positive and negative terminals to be connected within the string 200. The negative and positive terminals 200a and 200b of the string 200 are connected with a combiner box 120 (as depicted in FIG. 1), to supply power to the PV inverter 130 (also depicted in FIG. 1) The string 200 is not limited to connecting a particular number of PV panels 110, and may vary as desired. The bypass module 250 is between the outputs of the PV panels 110, for example, as shown between PV panel 19 and the PV panel 20, i.e., at the input and output of PV panel 20. The bypass module 250 includes a pair of solid state switches 260 and 262 (e.g., SS1 and SS2). According to some embodiments, the switches 260 and 262 are metal-oxide-semiconductor field-effect transistors (MOSFETs). However, the present invention is not limited hereto and any suitable switches may be used.

As shown in FIG. 2, in normal operation, if PV voltage is under the threshold for operation of the bypass module 250 then switch 260 is closed and conducting current to PV panel 20. When excess voltage is detected, then switch 262 is closed to short circuit PV panel 20. The current of the string 200 of approximately 8.66 amps (A) now flows into switch 262 and PV panel 20 short circuit current of approximately 9.15 amps (A) starts flowing in the reverse direction. Thus, the net current in switch 262 is approximately 0.49 amps (A). Optionally, according to an embodiment of the present invention, the switch 260 can then be open to reduce any increase in temperature of PV panel 20. If the switch 260 is open, then the open circuit (OC) voltage at PV panel 20 can be measured to determine the temperature of PV panel 20 and to provide power supply to bypass module 250.

When the total PV voltage across the string 200, or the PV panel 20 OC voltage drops to a sufficient level, then switch 260 can be re-closed and switch 262 can be opened.

A control module 300 as shown in FIG. 3 is also provided. The control module 300 is configured to monitor and control operation of all of the components shown in FIG. 3 except PV panel 210 which corresponds to PV Panel 20 shown in FIG. 2, for example. As shown in FIG. 3, the PV panel 210 includes positive and negative terminals thereof connected within the string 200 which includes the negative and positive terminals 200a and 200b. The PV panel 210 includes a photocell 160 comprising a diode 162 (e.g. a body diode) and a plurality of resistors 164 (e.g., Rs and Rsh). The control module 300 is connected to the PV panel 210 and includes a bypass module including a plurality of switches 310 and 312 (MOS1 and MOS2) which correspond to the bypass module 250 including switches 260 and 262, respectively as shown in FIG. 2), timer devices 314 and 316, a voltage sensor 318, filter device 320 and a comparator circuit 325 that includes a plurality of comparators 326 and 328 connected to a logic device 330 (e.g. an AND gate).

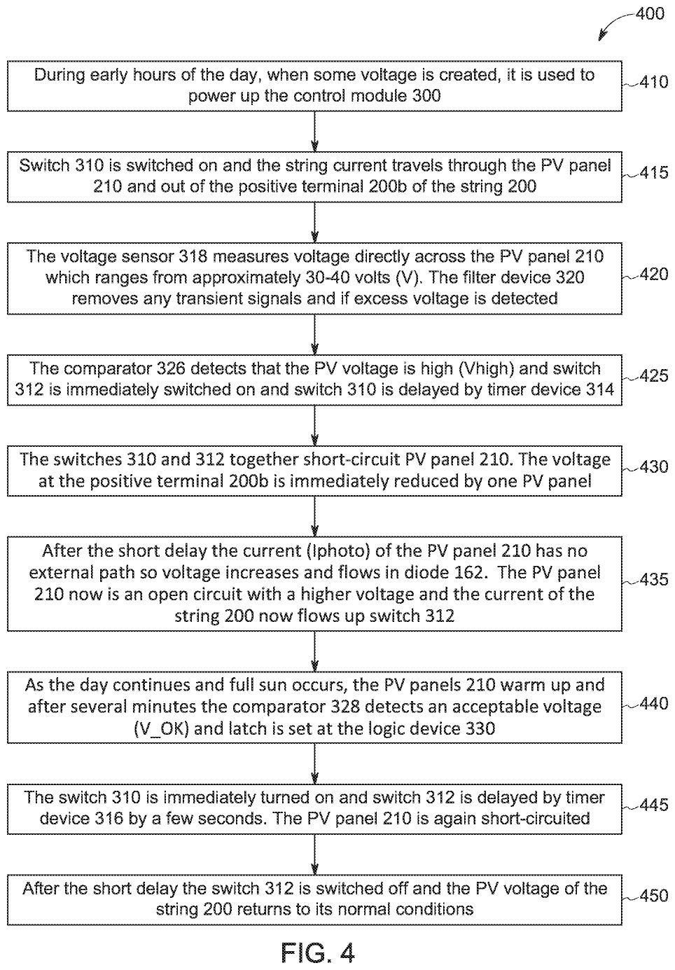

Operation of the bypass module as controlled by the control module 300 will be described below with reference to FIGS. 3 and 4. In FIG. 3, solar energy creates current (Iphoto) which flows in a direction towards the positive terminal 200b of the string 200 (as depicted in FIG. 3); and the voltage of the PV panel 210 is dominated by the diode 162 which re-absorbs some of PV energy. The PV voltage can change due to changes in the temperature of the PV panel 210. For example, heat (e.g., in a full sun environment) causes the PV voltage to decrease and lower temperatures, cool or cold (e.g., cloudy or cold environment) causes the voltage to be increased beyond normal operation. In FIG. 4, the process begins at operation 410 where during early hours of the day, when some voltage is created, it is used to power up the control module 300. According to an embodiment, power supply of the control module 300 for the bypass module 250 can be derived from the PV panel 210 and it only operates with PV energy.

At operation 415, the switch 310 is switched on and the string current travels through the PV panel 210 and out of the positive terminal 200b of the string 200. At operation 420, the voltage sensor 318 measures voltage directly across the PV panel 210 which ranges from approximately 30-40 volts (V). The filter device 320 removes any transient signals. Then at operation 425, the comparator 326 detects that the PV voltage is high (Vhigh) and switch 312 is immediately switched on and switch 310 is delayed by timer device 314 for approximately a few seconds. As a result, at operation 430, the switches 310 and 312 together short-circuit PV panel 210. The voltage at the positive terminal 200b is immediately reduced by one PV panel (e.g., in this case by the short-circuit of PV panel 210). The current of string 200 is reduced since the voltage is lower with the excess short-circuit current from the PV panel 210 flowing down in switch 312. At operation 435, after the short delay switch 310 opens and the current (Iphoto) of the PV panel 210 has no external path so voltage increases and flows in diode 162. The PV panel 210 now is an open circuit with a higher voltage and the current of the string 200 now flows up switch 312. At operation 440, once sufficient sun and time (several minutes) occurs, the PV panels 210 warm up the comparator 328 detects an acceptable voltage (V_OK) and latch is set at the logic device 330. At operation 445, the switch 310 is immediately switched on and switch 312 is delayed by timer device 316 by a few seconds. The PV panel 210 is again short-circuited, and at operation 450, after the short delay the switch 312 is switched off and the PV voltage of the string 200 returns to its normal conditions.

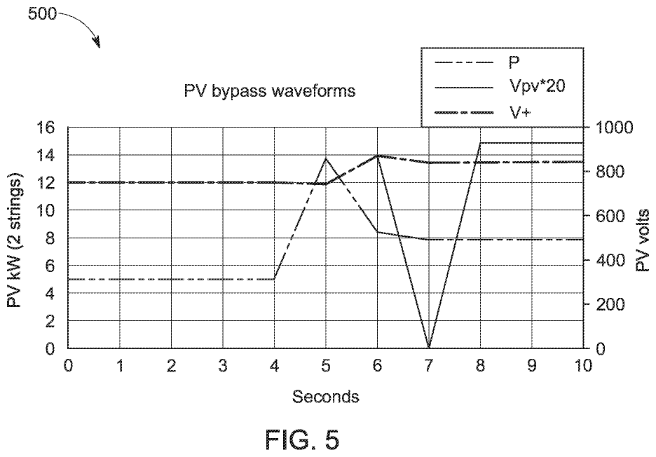

FIG. 5 is graph 500 illustrating an example of PV bypass waveforms occurring under certain environmental conditions, when implementing the bypass module 250 as depicted in FIGS. 2 and 3. In the example, there are one string of 20 PV panels and another string of 20 PV Panels with one bypass module employed (i.e., a total of 40 PV Panels). In the example, the temperature is assumed to be constant at 25° C. The sun irradiance is assumed to be 40% at approximately four (4) seconds, increasing to 110% by approximately five (5) seconds and staying at 110%. Power is kW into a converter nominal rated 8 kilowatts (kW). PV voltage is DC voltage input into a converter with a maximum power rating of approximately 850 volts (V). As shown in FIG. 4, from zero (0) to four (4) seconds, the environmental conditions is cloudy, and PV array system is operating at a maximum power point tracking (MPPT) power to a maximum power of approximately 5 kilowatts (kW) with the DC voltage of approximately 750 volts (V) which falls within an acceptable voltage range.

From four (4) to five (5) seconds, the sun comes out, thereby causing the MPPT power to increase to approximately 14 kilowatts (kW) which is considered excess power. From five (5) to six (6) seconds, the converter reacts to curtail the power to near 8 kilowatts (kW) increasing the voltage to approximately 850 volts (V) but decreasing the current. From six (6) to seven (7) seconds, the bypass module operates and the switch 312 shown in FIG. 3, shorts the PV panel and the voltage falls to zero thereby reducing the overall DC voltage to approximately 840 volts (V). From seven (7) to eight (8) seconds the switch 310 switches to PV panel to an open circuit having a OC voltage of approximately 928/20 volts (V). Then, from eight (8) to ten (10) seconds the bypass module continues to operate for a few minutes until the heat from the sun warms the PV panels. With higher temperatures the OC voltage is reduced to a safer, acceptable voltage range and the bypass module is able to be switched off.

The bypass module of the embodiments of the present invention provides several advantages. Some of the advantages include enhancement of the PV array system DC to AC ratio capacity, and lowering of arc fault energy and manufacturing costs.

This written description uses examples to disclose the invention including the best mode, and also to enable any person skilled in the art to practice the invention, including making and using any devices or apparatuses and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A control system for a PV array system including a plurality of PV panels, comprising:
a bypass module comprising:
a first switch device and a second switch device disposed at at least one PV panel connected with others of the plurality of PV panels along a string, and configured to perform a switching operation when voltage at the at least one PV panel is outside of an acceptable voltage range of the PV array system, wherein the bypass module is configured to short-circuit the at least one PV panel when excess voltage at the at least one PV panel is detected; and
a control module connected to the at least one PV panel and configured to monitor and control operation of the bypass module.

2. The control system of claim 1, wherein the first switch device is connected between an output of an adjacent PV panel and an input of the at least one PV panel on the sting and is configured to close and conduct current when the voltage is within an acceptable voltage range, to operate the bypass module.

3. The control system of claim 2, wherein the second switch device is connected between the output of the adjacent PV panel and an output of the at least one PV panel, and when the excess voltage is detected second switch device is configured to close to thereby short circuit the at least one PV panel.

4. The control system of claim 3, wherein current on the string flows to the second switch device and short-circuit current starts flowing in a reverse direction.

5. The control system of claim 4, wherein the first switch device is configured to open to decrease any increase in temperature at the at least one PV panel.

6. The control system of claim 5, wherein the control module comprises:
a first timer device and a second timer device each configured to initiate time delays on the first switch device and the second switch device, respectively;
a voltage sensor configured to measure voltage across the at least one PV panel;
a filter device connected to the voltage sensor and configured to filter any transient signals from the at least one PV panel; and
a comparator circuit comprising:
a first comparator configured to detect when the voltage is above the acceptable voltage range,
a second comparator configured to detect when the voltage is within the acceptable voltage range, wherein the first comparator and the second comparator are connected with a logic device.

7. The control system of claim 6, wherein when the first switch device is switched on, current along the string travels through the at least one PV panel and the voltage sensor measures the voltage across the at least one PV panel, and the filter removes any transient signals.

8. The control system of claim 7, wherein if the first comparator detects that the voltage is above the acceptable voltage range, then the second switch device is immediately switched on and the first timer device delay initiates a time delay of the first switch device, and the first switch device and the second switch device together short-circuit the at least one PV panel.

9. The control system of claim 7, wherein if the second comparator detects that that voltage is within the acceptable voltage range, then a latch is set at the logic device and the first switch device is switched on and the second timer device initiates a time delay of the second switch device and the at least one PV panel is short-circuited again and after the time delay the second switch device is switched off.

10. A PV array system comprising:
a plurality of PV arrays configured to supply DC power;
a combiner box connected to the PV arrays via a plurality of strings;
a PV inverter configured to convert the DC power to AC power for an electric power system; and
a control system comprising:
a bypass module comprising:
a first switch device and a second switch device disposed at at least one PV panel connected with others of the plurality of PV panels along a string, and configured to perform a switching operation when voltage at the at least one PV panel is outside of an acceptable voltage range of the PV array system, wherein the bypass module is configured to short-circuit the at least one PV panel when excess voltage at the at least one PV panel is detected; and
a control module connected to the at least one PV panel and configured to (i) receive power from the PV array system and (ii) monitor and control operation of the bypass module.

11. The PV array system of claim 10, wherein the first switch device is connected between an output of an adjacent PV panel and an input of the at least one PV panel on the sting and is configured to close and conduct current when the voltage is within an acceptable voltage range, to operate the bypass module.

12. The PV array system of claim 11, wherein the second switch device is connected between the output of the adjacent PV panel and an output of the at least one PV panel, and when the excess voltage is detected second switch device is configured to close to thereby short circuit the at least one PV panel.

13. The PV array system of claim 12, wherein current on the string flows to the second switch device and short-circuit current starts flowing in a reverse direction.

14. The PV array system of claim 13, wherein the first switch device is configured to open to decrease any increase in temperature at the at least one PV panel.

15. The PV array system of claim 14, wherein the control module comprises:
a first timer device and a second timer device each configured to initiate time delays on the first switch device and the second switch device, respectively;
a voltage sensor configured to measure voltage across the at least one PV panel;
a filter device connected to the voltage sensor and configured to filter any transient signals from the at least one PV panel; and
a comparator circuit comprising:
a first comparator configured to detect when the voltage is outside of the acceptable voltage range,
a second comparator configured to detect when the voltage is within the acceptable voltage range, wherein the first comparator and the second comparator are connected with a logic device.

16. A bypass method for bypassing at least one PV panel of an PV array system including a plurality of PV panels, comprising:
connecting a bypass module including a first switch device, a second switch device and a short-circuit device between an input and output of the at least one PV panel;
switching on the first switch device and conducting current when voltage at the at least one PV panel is within an acceptable voltage range, to operate the bypass module;
switching on the second switch device when excess voltage is detected at the at least one PV panel; and
short-circuiting, via the bypass module, the at least one PV panel.

17. The bypass method of claim 16, further comprising:
when the first switch device is switched on, measuring voltage, via a voltage sensor across the at least one PV panel; and
removing, via filter, any transient signals.

18. The bypass method of claim 17, wherein switching on the second switch device further comprises:
detecting, via a first comparator, the voltage of the at least one PV panel is outside of the acceptable voltage range, and switching on the second switch device;
initiating, via a first timer device, a time delay of the first switch device; and
short-circuiting, via the first switch device and the second switch device together, the at least one PV panel.

19. The bypass method of claim 17, wherein switching on the first switch device further comprises:
detecting, via a second comparator the voltage of the at least one PV panel is within the acceptable voltage range;
setting a latch is set at a logic device connected with the second comparator and switching on the first switch device; and
initiating, via a second timer device, a time delay of the second switch device to short-circuit the at least one PV panel a second time, and after the time delay switching off the second switch device.
